(19) United States
(12) Patent Application Publication
(10) Pub. No.: US 2011/0041520 A1
(43) Pub. Date: Feb. 24, 2011

(54) CRYOSTAT AND BIOMAGNETIC MEASUREMENT SYSTEM WITH RADIOFREQUENCY SHIELDING

(76) Inventors: Sergio Nicola Erné, Neu-Ulm (DE); Hannes Nowak, Jena (DE)

Correspondence Address: BOSE MCKINNEY & EVANS LLP, 111 MONUMENT CIRCLE, SUITE 2700, INDIANAPOLIS, IN, 46204, US

(21) Appl. No.: 12/905,518

(22) Filed: Oct. 15, 2010

Related U.S. Application Data
(63) Continuation of application No. PCT/EP2009/002718, filed on Apr. 14, 2009.

(30) Foreign Application Priority Data
Apr. 16, 2008 (DE) DE102008019091.8

(51) Int. Cl. F25B 19/00; B23P 15/26; G01R 33/02

(52) U.S. Cl. 62/51.1; 29/890.035; 324/244

(57) ABSTRACT

An inventive cryostat for use in a biomagnetic measurement system. The cryostat comprises at least one inner vessel and at least one outer vessel, and at least one cavity arranged between the inner vessel and the outer vessel, wherein negative pressure can be applied to the cavity. At least one radiation shield for shielding the cryostat from electromagnetic radiation is housed in the cavity. The cryostat furthermore comprises at least one ground lead for connecting the radiation shield to an electrical ground or earth. The ground lead is connected to the radiation shield in the cavity. The cryostat has at least one electrical feed-through, by means of which the ground lead can be contacted electrically from an outer side of the cryostat through the outer vessel.

### RELATED APPLICATIONS

This application is a continuation of PCT/EP2009/002718, filed Apr. 14, 2009, which claims priority to DE 10 2008 019 091.8, filed Apr. 16, 2008, both of which are hereby incorporated by reference in their entirety.

### BACKGROUND

The invention relates to a cryostat particularly suitable for use in a biomagnetic measurement system, and also to a biomagnetic measurement system comprising such a cryostat. The invention furthermore relates to a method for producing a cryostat particularly suitable for biomagnetic measurements. Such cryostats, measurement systems and methods can more particularly be used in the field of cardiology or else in other medical fields, such as neurology. Other applications, for example non-medical applications, for example applications in materials science and materials testing, are also feasible.

In recent years, magnetic measurement systems, which were previously restricted in essence to use in basic research, found their way into many areas of the biological and medical sciences. Neurology and cardiology in particular profit from such biomagnetic measurement systems.

Biomagnetic measurement systems are based on the fact that most cell activities in the human or animal body are connected with electrical signals, more particularly electrical currents. The direct measurement of such electrical signals caused by cell activity is known, for example, from the field of electrocardiography. However, in addition to the purely electrical signals, the electrical currents are also connected with a corresponding magnetic field, the measurement of which is used by the various known biomagnetic measurement methods.

Whereas the electrical signals, or the measurement thereof outside of the body, are connected with different factors such as the different electrical conductivities of the tissue types between the source and the body surface, magnetic signals penetrate these tissue regions almost unhindered. Measuring these magnetic fields and the changes therein thus allows conclusions to be drawn about the currents flowing within the tissue, for example electrical currents within the myocardium. Measuring these magnetic fields over a certain region with a high temporal and/or spatial resolution thus allows imaging methods that, for example, can reproduce a current situation in different regions of a human heart. Other known applications are found, for example, in the field of neurology.

However, measuring magnetic fields in biological samples or patients, or measuring temporal changes in these magnetic fields, constitutes a large metrological challenge. Thus, by way of example, the changes in the magnetic field in the human body, which are intended to be measured in magnetocardiography, are approximately one million times weaker than the Earth's magnetic field. Thus, detecting these changes requires extremely sensitive magnetic sensors. Therefore, superconducting quantum interference devices (SQUIDs) are used in most cases in the field of biomagnetic measurements. In general, such sensors must typically be cooled to 4 K (−269° C.) to attain or maintain the superconducting state, for which purpose liquid helium is usually used. Therefore, the SQUIDs are generally arranged individually or in a SQUID array in a so-called Dewar flask and are correspondingly cooled at said location. As an alternative, laser-pumped magneto-optic sensors are currently being developed, which can have an almost comparable sensitivity. In this case, the sensors are also generally arranged in an array arrangement in a container for the purpose of stabilizing the temperature.

Such containers for stabilizing the temperature, more particularly containers for cooling magnetic sensors and so-called Dewar flasks, are in general referred to as “cryostats” in the following text. In particular, these can be helium cryostats or other types of cryostats. Herein, no distinction is made in the following text between the cryostat and the cryostat vessel, which is also referred to as a Dewar, even though the actual cryostat may comprise additional parts in addition to the cryostat vessel.

It is a big challenge in terms of the design to produce the cryostat for housing biomagnetic sensor systems. The sensors are usually introduced into this cryostat in a predetermined arrangement, for example in the form of a hexagonal arrangement of SQUIDs or other magnetic sensors. Here, the cryostat usually comprises an inner vessel, with sensors housed therein, and an outer vessel. The interspace between the inner vessel and outer vessel is evacuated. However, in the process, it is very important for the distance between the sensors housed in the inner cryostat vessel and the surface of the skin of the patient to be kept as small as possible, because, for example, the signal strength reduces with a high power of the distance between the sensor and the surface of the skin. Accordingly, the distance between the bases of the inner and outer vessels has to remain small and very constant.

The prior art has disclosed a large number of cryostats that can be used for magnetic measurements. Thus, for example, W. Andra and H. Nowak: Magnetism in Medicine, 2nd Edition, Wiley-VCH Verlag, Weinheim, 2007, pp. 116-117, describe a cryostat that can be used for biomagnetic measurements on the basis of superconducting magnetic sensors. Other examples of cryostats are for example known from U.S. Pat. No. 4,827,217 and WO 98/06972 A1.

A particular challenge in the case of cryostats that are intended to be used in biomagnetic measurement systems consists of the fact that the sensors used for the actual biomagnetic measurement have a comparatively large bandwidth for recording magnetic or electromagnetic signals. Thus, for example, superconducting SQUIDs are sensitive to signals from the low-frequency range at approximately 0.01 Hz and up to the microwave spectrum, that is to say to the gigahertz to terahertz band. However, the actual measurement signals lie in the low-frequency range, typically between 0.01 Hz and 2000 Hz. Electronics in particular, usually required for actuating and evaluating the sensors, or else other sources of noise however produce interference radiation that can lead to a significant deterioration in the signal quality of the measurement signals. Therefore, local shielding of the sensors is required from radiofrequency irradiation up to the microwave band. The challenge of this radiation shielding has only partly been solved in a satisfactory manner in the previously known cryostats, such as the cryostat described in the aforementioned publication by W. Andra and H. Nowak and comprising radiation shields, and there is room and need for further improvement.

### SUMMARY

The present invention provides a cryostat which at least to a large extent avoids the above-described disadvantages of known cryostats. More particularly, the disclosed cryostat on the one hand ensures high signal quality in biomagnetic measurements and on the other hand is suitable for housing sensors for the biomagnetic measurements.

A cryostat for use in a biomagnetic measurement system is disclosed, that is to say a vacuum-insulated container within the sense of the description above, which cryostat is suitable for housing at least one biomagnetic sensor, more particularly at least one SQUID or at least one SQUID array. The disclosed cryostat comprises at least one inner vessel, for example an inner vessel that can be filled with liquid helium, and also an outer vessel surrounding the inner vessel at least in part. Here, the inner vessel is arranged relative to the outer vessel such that at least one cavity is formed at least in portions between the inner and outer vessel. The cavity is designed such that it can be evacuated, i.e. a negative pressure can be applied thereto, for example as a result of an appropriate seal of the joint between the inner and outer vessel. For this purpose, the cryostat can for example additionally be provided with at least one vacuum valve, that is to say a valve that can be connected to a vacuum pump outside of the cryostat.

In the cavity at least one radiation shield is housed for at least partly shielding the cryostat, or the at least one biomagnetic sensor that can be housed in the interior of the cryostat, from electromagnetic radiation. By way of example, the radiation shield can wholly or partly be embodied as a metallic radiation shield, that is to say as a radiation shield with at least one metallic material.

Exemplary embodiments improve radiation shielding from electromagnetic radiation, more particularly in the radiofrequency range, by virtue of the fact that an option is developed for grounding the at least one radiation shield. In usual, conventional cryostats, some of which already have metallic radiation shields, like, for example, the cryostat described in the aforementioned publication by W. Andra and H. Novak, such radiation shields have already been disclosed in part. However, these radiation shields are not grounded and nor is an option for grounding these radiation shields even provided. However, it was found that grounding, that is to say connecting the radiation shield with an electrical ground and/or an electrical earth, can lead to a significant improvement in the shielding, and hence in the signal quality.

Accordingly, it is proposed to equip the cryostat with at least one ground lead at least partly arranged in the cavity. This ground lead is used to connect the radiation shield to an electrical ground and/or earth. The ground lead is connected in the cavity to the radiation shield for this purpose. The cryostat in turn has at least one electrical feed-through, more particularly at least one electrical feed-through in the at least one outer vessel, by means of which feed-through the ground lead can be electrically contacted and grounded from an outer side of the cryostat.

Thus, the proposed cryostat offers significant advantages in respect of radiofrequency shielding compared to cryostats known from the prior art. The “grounding” of the shield is not limited to the volume, and possibly the metallic ground, of the radiation shields within the cryostat itself, which can be restricted for structural reasons, but use can be made of an external electrical ground or electrical earth that can be optimized as desired and is not limited by the cryostat volume in respect of its quality.

Electrical feed-throughs, more particularly through vacuum-tight outer vessels, have technical challenges relating to their requirements in respect of the vacuum-tightness that have to be solved by comparatively high structural complexity. In this context, it is desirable that the electrical feed-through at least in part comprises at least one vacuum valve. Such vacuum valves are generally available anyhow in the mentioned cryostats because, for example, the cavity between the inner vessel and the outer vessel can be evacuated with the help of these valves. The term “vacuum valve” should be interpreted broadly in this context and can, in principle, for example comprise any opening, for example a port, as an alternative or in addition to a valve as such, by means of which a vacuum can be applied to the cavity. The term “vacuum valve” thus includes, e.g. valves, vacuum ports, vacuum seals or similar devices. Thus, the vacuum valve for example on the outer side of the cryostat can be provided with an appropriate port or connection for connecting a vacuum pump to this vacuum valve. After the evacuation, this vacuum valve can for example be sealed, and so the vacuum valve can for example have a vacuum seal. Alternatively, or in addition thereto, the vacuum valve can also comprise a safety valve, for example to stop the cryostat imploding. Other refinements are also feasible.

In one embodiment, the at least one vacuum valve, wholly or partly, is embodied in a structurally identical fashion to the electrical feed-through. Thus, an additional electrical feed-through is no longer required. This embodiment can be implemented in a particularly simple fashion if the vacuum valve has at least one at least partly metallic component and this metallic component, which preferably completely penetrates the outer vessel, can then be used as a component of the ground lead. By way of example, the ground lead can comprise a first, flexible conductor, which connects the at least one radiation shield to the metallic component of the vacuum valve, with the vacuum valve or the metallic component thereof then itself forming a second part of the ground lead. Further parts of the ground lead can be provided. The metallic component can for example comprise a housing of the vacuum valve, a metallic port of the vacuum valve or a similar metallic component, preferably a metallic component which penetrates the outer vessel entirely or preferably completely.

Exemplary embodiments can implement the option of grounding and conducting away the radiation shield potential from the outside of the cryostat vessel in a particularly simple fashion. Since the vacuum valves usually already have a high vacuum tightness, additional, sealing measures can be dispensed with. Contacting the feed-through from the outside can then for example be brought about in turn by means of flexible conductors, a screw connection, a clamping connection or other types of electrical connections in order to connect the electrical feed-through to the ground or earth on the outer side of the cryostat.

Further preferred embodiments relate to the design of the radiation shield. Thus, it is particularly preferred if the radiation shield comprises a layered design with at least two metallic layers lying above one another. These metallic layers should be electrically interconnected by an ohmic connection and/or a capacitive connection. The connection between the at least one radiation shield and the ground lead can also be brought about by an ohmic and/or capacitive connection.

The radiation shield should preferably be designed to, as a whole, bring about shielding of electromagnetic radiation by at least 5 dB in a frequency range between 100 kHz and one GHz.

By way of example, this shielding can be ensured by virtue of the fact that the radiation shield comprises one or more metal foils and/or meshes (for example metallic meshes) and/or foils produced from bonded wires (coil foils). These metal foils can for example comprise an aluminum foil, a copper foil, a silver foil, a gold foil or a foil with any combination of these materials. Aluminum foils, for example aluminum foils in the form of self-adhesive aluminum adhesive tapes, have particularly proven their worth in practical use. By way of example, aluminum adhesive tapes with a width of 50 mm and an aluminum thickness of 70 μm can be used. In general, the metal foil thicknesses can be between 5 μm and 500 μm, more particularly between 10 μm and 100 μm, with the specified thicknesses of 70 μm being preferred. Overall, the metal foils can comprise self-adhesive metal foils.

As in the aforementioned publication by W. Andra and H. Nowak, it is particularly preferable for at least one superinsulation layer for shielding heat radiation to be arranged in the at least one cavity. This at least one superinsulation layer has a material with a thermal conductivity that is as low as possible, for example a nonmetallic material, for example a plastics material. More particularly, the superinsulation layer can be embodied as a superinsulation foil, for example as a superinsulation foil with a thickness in the region of between 10 μm and 1 mm, for example with a thickness of approximately 100 μm. The use of plastics foils, for example polyethylene foils, e.g. Mylar foils, is particularly preferred.

The superinsulation layer can additionally comprise at least one metallic coating on at least one side. This at least one-sided metallic coating, which, for example, can be applied onto a polyethylene foil of the superinsulation layer, can, for example, comprise an aluminum layer and/or a layer made of one of the other aforementioned metals. By way of example, a coating can be applied in the region of 500 nm up to 50 μm, preferably in the range between 8 μm and 10 μm. However, contrary to the actual radiation shield, it is particularly preferable for this at least one metallic coating not to be electrically connected to the ground lead, although this equally may be the case.

A plurality of superinsulation layers and a plurality of radiation shields can be arranged, more particularly alternately, in the cavity. By way of example, using a winding method for example, aluminum-coated polyethylene foils, as superinsulation layers, and self-adhesive aluminum adhesive tapes can alternately be introduced into the cavity, with the aluminum adhesive tapes being connected to the ground lead. This can bring about good thermal shielding by the ungrounded superinsulation layers and also radiofrequency shielding by the layers of the radiation shields in a particularly efficient manner. By way of example, respectively three layers of the superinsulation layers and of the radiation shields can be layered above one another, for example wound above one another. However, respectively one layer, respectively two layers or a greater number of layers are also feasible.

In addition to the cryostat in one or more of the above-described embodiments, a biomagnetic measurement system is furthermore proposed, which comprises at least one cryostat according to one or more of the above-described embodiments. The biomagnetic measurement system furthermore comprises at least one biomagnetic sensor for detecting one or more magnetic fields. By way of example, this biomagnetic sensor can comprise at least one superconducting quantum interference device (SQUID) and/or an array of such SQUIDs. Alternatively, or in addition thereto, use can also be made of other types of magnetic sensors, for example magneto-optic sensors. The at least one biomagnetic sensor is preferably housed in the at least one inner vessel, for example in one or more recesses in the underside of the inner vessel such that, for example, the at least one sensor can be in direct contact with the coolant, for example the liquid helium.

In addition to the cryostat and the sensor, the biomagnetic measurement system can additionally comprise a multiplicity of further components. By way of example, the biomagnetic measurement system can comprise actuation and evaluation electronics, which can be arranged outside of and/or wholly or partly within the cryostat. In the case of an arrangement outside of the cryostat, electrical feed-throughs can for example be provided in the cover region of the cryostat in order to actuate or electronically read out the at least one sensor. Such actuation and evaluation circuits, in particular for SQUIDs, are known to a person skilled in the art from other biomagnetic measurement systems as per the prior art. The biomagnetic measurement system can additionally comprise further components, for example evaluation systems, measurement containers, patient couches or the like.

Here it is particularly suitable that the ground lead of the cryostat is connected to at least one electrical ground of the Earth. For this purpose, the at least one electrical feed-through can for example be connected to a laboratory ground or an electrical ground of a measuring station in the hospital, or a similar diagnosis apparatus.

In addition to the cryostat and the biomagnetic measurement system, a method for producing a cryostat for use in a biomagnetic measurement system is additionally proposed. In particular, the method can be used for producing the cryostat as per one or more of the above-described embodiments, and so reference can be made to the above description in respect of possible refinements of the cryostat that imply corresponding production steps. The cryostat in turn has an inner vessel, an outer vessel and at least one cavity between the inner vessel and outer vessel. The method steps described below can be carried out in the illustrated sequence, but can also be performed in a sequence that differs from the illustrated one. Thus, for example, individual specified method steps, or a plurality thereof, can also be carried out repeatedly or parallel in time or overlapping in time. Furthermore, additional method steps that have not been mentioned can also be carried out.

In one method step, the inner vessel of the cryostat is produced first of all. Furthermore, at least one radiation shield for shielding the cryostat from electromagnetic radiation is produced, with the radiation shield preferably at least partly surrounding the inner vessel. As described above, this can for example be implemented by means of a winding technique, for example by means of a winding technique in which the at least one radiation shield is directly or indirectly wound onto the at least one inner vessel.

In a further method step, the outer vessel of the cryostat is produced and assembled with the inner vessel such that at least one cavity that can be evacuated is arranged between the inner vessel and the outer vessel. By way of example, the inner vessel and the outer vessel can be produced, wholly or partly, from plastics, for example reinforced plastics. Thus, for example, use can be made of a glass fiber-reinforced plastic, for example an epoxy. By way of example, plastics, for example glass fiber-reinforced plastics, with a wall thickness of approximately 1 mm can be used as a base body for the inner vessel. It is also possible for a plurality of such base bodies to be boxed within one another. By way of example, two, three or more plastics cylinders, for example glass fiber-reinforced plastics cylinders, can be boxed within one another in order to produce the inner vessel. The outer vessel can be produced using a similar production technique. For assembling the inner vessel and outer vessel and for generating the cavity that can be evacuated, appropriate bonding techniques can be used; however, other assembly techniques can also be used. In the process, the assembly is carried out such that the radiation shield is at least partly housed in the cavity. The assembly is furthermore carried out such that the outer vessel comprises at least one electrical feed-through, with the radiation shield being electrically connected to the feed-through via at least one ground lead. By way of example, a winding technique can be used to produce the radiation shield, in which the radiation shield can for example wholly or partly be wound onto the inner vessel. Additionally, it is also possible, as described above, for use to be made of one or more superinsulation layers, which for example can be wound up alternately with the radiation shields or can be introduced into the cryostat in any other fashion.

### BRIEF DESCRIPTION OF DRAWING

The above-mentioned aspects of exemplary embodiments will become more apparent and will be better understood by reference to the following description of the embodiments taken in conjunction with the accompanying drawing, wherein:

FIG. 1 shows a sectional illustration of an exemplary embodiment of a biomagnetic measurement system with a cryostat.

### DETAILED DESCRIPTION

The embodiments of the present invention described below are not intended to be exhaustive or to limit the invention to the precise forms disclosed in the following detailed description. Rather, the embodiments are chosen and described so that others skilled in the art may appreciate and understand the principles and practices of the present invention.

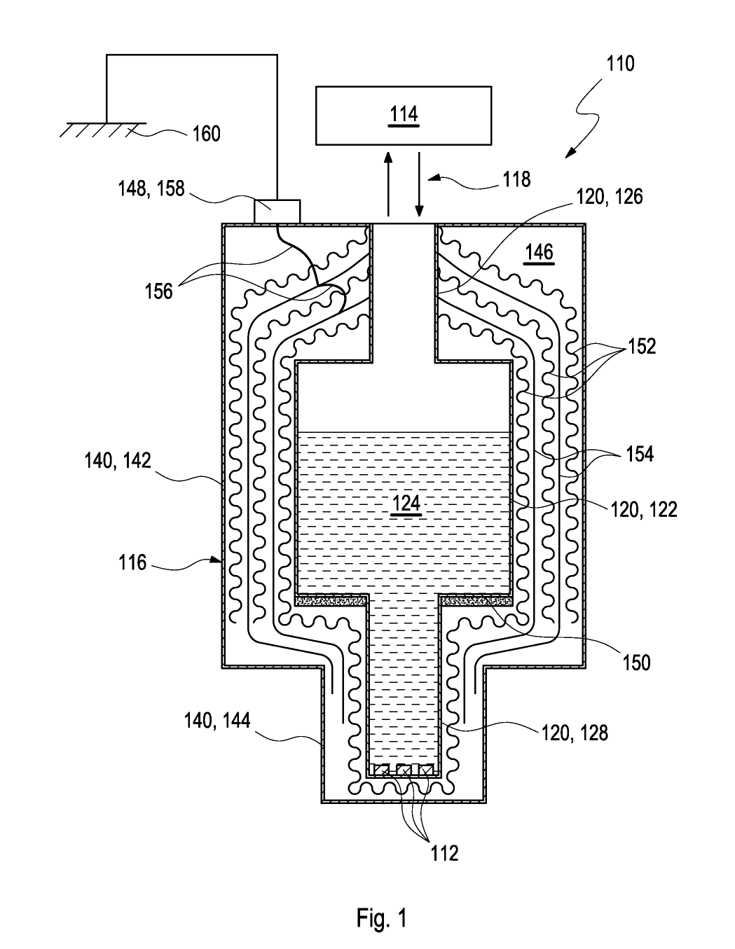

FIG. 1 schematically shows a sectional illustration of an exemplary embodiment of a biomagnetic measurement system 110 from the side. In the illustrated exemplary embodiment, this biomagnetic measurement system 110 comprises a plurality of magnetic sensors 112, actuation and evaluation electronics 114, and also a cryostat 116. By way of example, the magnetic sensors 112 can comprise an array of SQUIDs, which can be connected to the actuation and evaluation electronics 114 via electrical connections 118, which are merely indicated symbolically in FIG. 1.

The cryostat comprises an inner vessel 120, which can for example be substantially cylindrically symmetrical. By way of example, the inner vessel 120 comprises a main tank 122, into which for example liquid helium 124 at 4.2 K can be introduced, and also a narrowed neck tube 126 on the upper side of the main tank 122 and a finger 128, likewise narrowed with respect to the main tank 122, on the lower side of the main tank 122. The magnetic sensors 112 can be introduced into the finger 128 on the lower side of the finger 128, for example in recesses in the wall of the inner vessel 122, such that the distance between the magnetic sensors 112 and a patient (not illustrated in FIG. 1) arranged below the cryostat 116 in FIG. 1 is as small as possible.

In the exemplary embodiment as per FIG. 1, the cryostat 116 furthermore comprises an outer vessel 140, which at least to a large extent surrounds the inner vessel 120. Here the outer vessel 140 in turn has substantially cylindrical symmetry, with a main tank 142 and a finger 144 surrounding the finger 128 of the inner vessel 120. A cavity 146 that can be evacuated is formed between the inner vessel 120 and the outer vessel 140. This means that the connections between the inner vessel 120 and the outer vessel 140 are brought about in such a fashion that negative pressure, which can be generated by pumping away atmosphere from the cavity 146, can be maintained over a period of a number of hours, preferably over a period of a number of days or weeks. For this purpose, the outer vessel 140 of the cryostat 116 furthermore has at least one vacuum valve 148, which can, in the illustrated exemplary embodiment, for example be arranged on the upper side of the main tank 142 of the outer vessel 140. As an alternative to evacuating the cavity 146, or in addition thereto, the vacuum valve 148 can also comprise a safety valve or other types of vacuum valves 148.

An absorber 150 can be provided on the base part of the main tank 122 of the inner vessel 120, for example on an end face of the main tank 142 surrounding the finger 128. By way of example, activated carbon, zeolite and/or other porous materials can be used as an absorber 150. Alternatively, or in addition thereto, such absorbers 150 can also be provided at other locations in the cryostat 116, more particularly in the inner vessel 120.

During use of the cryostat 116, the outer vessel 140 is approximately at room temperature, whereas the inner vessel 120 is cooled down to liquid-helium temperature. In order to maintain this temperature difference over a relatively long period of time, superinsulation layers 152 are arranged in the cavity 146. In the illustrated exemplary embodiment, three such layers of superinsulation layers 152 are provided, at least in the region of the main tank 122. By way of example, the inner vessel 120 can comprise cylindrical base bodies made of glass fiber-reinforced epoxy plastics, each with a wall thickness of 1 mm. By way of example, three such glass fiber-reinforced plastic cylinders can be boxed within one another. The first superinsulation layer 152 can then be wound onto this base body of the inner vessel 120, which superinsulation layer can for example comprise a polyethylene foil (Mylar) coated on one side with an 8 μm thick aluminum layer. The superinsulation layers 152 can wholly or partly surround the inner vessel 120. By way of example, in the illustrated exemplary embodiment, the innermost superinsulation layer 152 completely surrounds the inner vessel 120, that is to say also the region of the finger 128 including the end face of this finger 128 housing the magnetic sensors 112, whereas the remaining layers of the superinsulation layers 152 merely surround the neck tube 126 and the main tank 122. However, other refinements are also feasible, for example a different number of superinsulation layers 152, a different distribution of the superinsulation layers or the like.

Furthermore, a plurality of radiation shields 154, which should at least in part prevent radiation of electromagnetic radiofrequency radiation into the interior of the inner vessel 120 of the cryostat 116, are provided in the cavity 146 in the exemplary embodiment illustrated in FIG. 1. Here, in turn, merely part of the inner vessel 120 is surrounded by these radiation shields 154 in the illustrated exemplary embodiment, for example the neck tube 126 and the main tank 122, and also part of the finger 128. However, another arrangement is yet again also feasible, for example an arrangement in which one or a few of these radiation shields 154 also completely surround the finger 128, or a relatively large section of this finger 144, such that the magnetic sensors 112 in the finger 128 have increased shielding. However, the downward-facing end face of the finger 144, through which the actual signal recording of the magnetic sensors 112 takes place, is preferably not covered by the radiation shields 154.

It is particularly preferable for the radiation shields 154 to comprise a self-adhesive aluminum tape. By way of example, use can be made of an aluminum adhesive tape that has a width of 50 mm and a thickness of approximately 70 μm. The radiation shields 154 bring about the actual effect of radiation shielding for the cryostat 116 from electromagnetic radiation, for example radiation in the spectrum between 100 kHz and 1 GHz. In the illustrated exemplary embodiment, use is made of an alternating structure of superinsulation layers 152 and radiation shields 154. For this purpose, layers of the superinsulation layers 152 and the aluminum adhesive tape of the radiation shields 154 can, in the cavity 146 and alternately in each case, be wound onto the base body of the cylindrically symmetrical inner vessel 120.

While the optionally present metallization of the superinsulation layers 152 is not additionally contacted in the illustrated exemplary embodiment, the radiation shields 154 are connected to a ground lead 156. This ground lead 156 is illustrated symbolically in FIG. 1 and can, for example, comprise one or more flexible electrical connections, through-contacts, rigid electrical connections or the like. The coupling can be brought about via an ohmic electrical connection and/or a capacitive linkage. The radiation shields 154, or at least some of these radiation shields 154, are electrically interconnected via the ground lead 156. Furthermore, the radiation shields 154 are connected via the ground lead 156 to the vacuum valve 148, which at the same time acts as an electrical feed-through 158. This affords the possibility of dispensing with an additional electrical feed-through 158. For this purpose, the vacuum valve 148 is preferably wholly or partly embodied as a metallic vacuum valve. This affords the possibility of grounding the radiation shields 154 outside of the cryostat 116, for example by connecting the vacuum valve 148, for example the evacuation valve, to a laboratory ground 160 outside of the cryostat 116.

The exemplary embodiment of the cryostat 116 and the biomagnetic measurement system 110 illustrated in FIG. 1 brings about simple and efficient shielding of the magnetic sensors 112 from electromagnetic interference, for example electromagnetic interference caused by the actuation and evaluation electronics 114 of the biomagnetic measurement system 110 itself The originally present shielding by the superinsulation layers 152 is efficiently increased by the radiation shields 154 such that the latter act as a radiofrequency shield. By making these radiation shields 154 accessible via the vacuum valve 148, reliable grounding and, as a result thereof, an improvement in the signal quality can be ensured.

The layered design shown in FIG. 1 can also be produced in a simple fashion, in particular by using the above-described winding technique. In the process, the winding can be brought about for example in a loose fashion by the individual layers being wound onto the inner vessel 120 with mechanical play. This can also allow contacting of the foil packets of the radiation shields 154 amongst themselves to be brought about without problems. This wound layered design can then be inserted into the outer vessel 140, after which a cover plate, for example, of the outer vessel 140 can be put on in order to ensure the cavity 146 being vacuum-tight. This affords the possibility of producing the cryostat 116 illustrated in FIG. 1 in a cost-effective and reliable fashion.

While exemplary embodiments incorporating the principles of the present invention have been disclosed hereinabove, the present invention is not limited to the disclosed embodiments. Instead, this application is intended to cover any variations, uses, or adaptations of the invention using its general principles. Further, this application is intended to cover such departures from the present disclosure as come within known or customary practice in the art to which this invention pertains and which fall within the limits of the appended claims.

### LIST OF REFERENCE SIGNS

110 Biomagnetic measurement system
112 Magnetic sensors
114 Actuation and evaluation electronics
116 Cryostat
118 Electrical connections
120 Inner vessel
122 Main tank
124 Liquid helium
126 Neck tube
128 Finger
140 Outer vessel
142 Main tank of the outer vessel
144 Finger of the outer vessel
146 Cavity
148 Vacuum valve
150 Absorber
152 Superinsulation layers
154 Radiation shield
156 Ground lead
158 Electrical feed-through
160 Laboratory ground

What is claimed is:

1. A cryostat for use in a biomagnetic measurement system, comprising;
an inner vessel, an outer vessel and a cavity arranged therebetween, wherein negative pressure can be applied to the cavity;
a radiation shield for shielding the cryostat from electromagnetic radiation housed in the cavity;
a ground lead connected to the radiation shield in the cavity and adapted for connecting the radiation shield to an electrical ground or earth; and
an electrical feed-through configured to permit the ground lead to be contacted electrically from an outer side of the cryostat through the outer vessel, the electrical feed-through comprising at least one vacuum valve configured for evacuating the cavity.

2. The cryostat of claim 1, wherein the vacuum valve comprises an at least partly metallic component used as part of the ground lead.

3. The cryostat of claim 2, wherein the radiation shield comprises at least two metallic layers lying one above the another, the metallic layers being electrically interconnected by an ohmic connection and/or by a capacitive connection.

4. The cryostat of claim 1, wherein the radiation shield shields electromagnetic radiation by at least 5 dB in a frequency range between 100 kHz and 1 GHz.

5. The cryostat of claim 1, wherein the radiation shield comprises at least one of the following metal foils: aluminum; copper; silver and gold.

6. The cryostat of claim 1, wherein the radiation shield comprises at least one metal foil with a thickness between 5 micrometers and 500 micrometers.

7. The cryostat of claim 6, wherein the at least one metal foil has a thickness between 10 micrometers and 100 micrometers.

8. The cryostat of claim 7, wherein the at least one metal foil has a thickness of about 70 micrometers.

9. The cryostat of claim 1, wherein the radiation shield comprises at least one self-adhesive metal foil.

10. The cryostat of claim 1, further comprising at least one superinsulation layer arranged in the cavity for shielding against heat radiation.

11. The cryostat of claim 10, wherein the superinsulation layer comprises at least one plastic foil.

12. The cryostat of claim 11, wherein the at least one plastic foil comprises polyethylene.

13. The cryostat of claim 10, wherein the superinsulation layer comprises a metallic coating on at least one side thereof.

14. The cryostat of claim 10, wherein a plurality of superinsulation layers and a plurality of radiation shields are arranged alternately in the cavity.

15. A biomagnetic measurement system, comprising at least one cryostat as claimed in claim 1 and further comprising at least one biomagnetic sensor for detecting a magnetic field.

16. The biomagnetic measurement system of claim 15, wherein the ground lead of the cryostat is connected to at least one electrical ground or earth.

17. A method for producing a cryostat for use in a biomagnetic measurement system, comprising the following steps:
providing an inner vessel of the cryostat;
surrounding the inner vessel at least in part by a radiation shield;
providing an outer vessel having an electrical feed-through, the electrical feed-through comprising a vacuum valve;
arranging the outer vessel with the inner vessel to create a cavity that can be evacuated between the inner vessel and the outer vessel, wherein the radiation shield is housed at least in part in the cavity; and
connecting a ground lead through the electrical feed-through to the radiation shield.

18. The method of claim 17, further comprising winding the radiation shield onto the inner vessel.
